(19) United States
(12) Patent Application Publication
(10) Pub. No.: US 2019/0252433 A1
(43) Pub. Date: Aug. 15, 2019

(54) PHOTOELECTRIC CONVERSION DEVICE, PHOTOELECTRIC CONVERSION SYSTEM, AND MOVING BODY

(71) Applicant: CANON KABUSHIKI KAISHA, Tokyo (JP)

(72) Inventor: Hiromasa Tsuboi, Tama-shi (JP)

(21) Appl. No.: 16/272,088

(22) Filed: Feb. 11, 2019

(30) Foreign Application Priority Data
Feb. 15, 2018 (JP) 2018-025382

(51) Int. Cl. H01L 27/146

(52) U.S. Cl. CPC H01L 27/14612; H01L 27/14625; H01L 27/14689; H01L 27/14603

(57) ABSTRACT

A photoelectric conversion device, comprising a plurality of pixels each including: a photoelectric converter for accumulating charges generated by photoelectric conversion; a transfer transistor for transferring the charges accumulated at the photoelectric converter; and an overflow transistor for connecting the photoelectric converter with an overflow drain, wherein during an accumulation period in which the charges are accumulated at the photoelectric converter, a gate potential of the overflow transistor is set at a potential VofH, and wherein in at least some period during a transfer period in which the charges are transferred from the photoelectric converter by the transfer transistor, the gate potential of the overflow transistor is set at a potential VofL that is lower than the potential VofH.

### BACKGROUND OF THE INVENTION

### Field of the Invention

The present invention relates to a photoelectric conversion device, an photoelectric conversion, and a moving body.

### Description of the Related Art

U.S. Patent Application Publication No. 2006/0001060 (Specification) discloses a photoelectric conversion device (solid-state imaging element) capable of implementing a high dynamic range by using an overflow drain (hereinafter, OFD) transistor.

A photoelectric conversion device is required to be improved in the transfer efficiency when charges are transferred from a photoelectric converter to a different region.

### SUMMARY OF THE INVENTION

It is an object of the present invention to improve the transfer efficiency of charges in a photoelectric conversion device.

The first aspect of the present disclosure is a photoelectric conversion device, comprising a plurality of pixels each including: a photoelectric converter for accumulating charges generated by photoelectric conversion; a transfer transistor for transferring the charges accumulated at the photoelectric converter; and an overflow transistor for connecting the photoelectric converter with an overflow drain, wherein during an accumulation period in which the charges are accumulated at the photoelectric converter, a gate potential of the overflow transistor is set at a potential VofH, and wherein in at least some period during a transfer period in which the charges are transferred from the photoelectric converter by the transfer transistor, the gate potential of the overflow transistor is set at a potential VofL, that is lower than the potential VofH.

With the photoelectric conversion device according to the present invention, it becomes possible to improve the transfer efficiency of charges.

Further features of the present invention will become apparent from the following description of exemplary embodiments with reference to the attached drawings.

### BRIEF DESCRIPTION OF THE DRAWINGS

FIGS. 1A and 1B are respectively a circuit diagram and a plan schematic view of a photoelectric conversion device according to First Embodiment;

FIGS. 2A and 2B are respectively a timing view and a potential distribution view of the photoelectric conversion device according to First Embodiment;

FIGS. 3A and 3B are respectively a plan schematic view and a cross sectional schematic view of a photoelectric conversion device according to Second Embodiment;

FIG. 4 is a timing view of a photoelectric conversion device according to Third Embodiment;

FIGS. 5A and 5B are respectively a circuit diagram and a plan schematic view of a photoelectric conversion device according to Fourth Embodiment;

FIG. 6 is a timing view of the photoelectric conversion device according to Fourth Embodiment;

FIG. 7 is a plan schematic view of a photoelectric conversion device according to Fifth Embodiment;

FIGS. 8A and 8B are respectively a plan schematic view and a timing view of a photoelectric conversion device according to Sixth Embodiment;

FIGS. 9A and 9B are respectively a circuit diagram and a plan schematic view of a photoelectric conversion device according to Seventh Embodiment;

FIG. 10 is a timing view of the photoelectric conversion device according to Seventh Embodiment;

FIG. 11 is a circuit diagram of a photoelectric conversion device according to Eighth Embodiment;

FIGS. 12A and 12B are each a plan schematic view of the photoelectric conversion device according to Eighth Embodiment;

FIG. 13 is a circuit diagram of a photoelectric conversion device according to Ninth Embodiment;

FIG. 14 is a plan schematic view of the photoelectric conversion device according to Ninth Embodiment;

FIG. 15 is a timing view of the photoelectric conversion device according to Ninth Embodiment;

FIG. 16 is a circuit diagram of a photoelectric conversion device according to Tenth Embodiment;

FIG. 17 is a plan schematic view of the photoelectric conversion device according to Tenth Embodiment;

FIG. 18 is a view illustrating a configuration example of a photoelectric conversion system according to Eleventh Embodiment; and

FIGS. 19A and 19B are each a view illustrating a configuration example of a photoelectric conversion system and a moving body according to Twelfth Embodiment.

### DESCRIPTION OF THE EMBODIMENTS

Below, embodiments of the present invention will be described by reference to the accompanying drawings. Incidentally, the present invention is not limited to the following embodiments, and may be appropriately changed within the scope not departing from the gist thereof. Further, in the drawings described below, those having the same function are given the same reference numeral and sign, and a description thereon may be omitted or simplified.

A photoelectric conversion device is a semiconductor device having a plurality of pixels for converting light into an electric signal, and is also called a solid-state imaging element, an image sensor, or a photoelectric conversion device. The photoelectric conversion devices include a CCD image sensor, a CMOS image sensor, and the like. Below, as one of preferable application examples of the present invention, a description will be given to a configuration example when the present invention is applied to a CMOS image sensor.

### First Embodiment

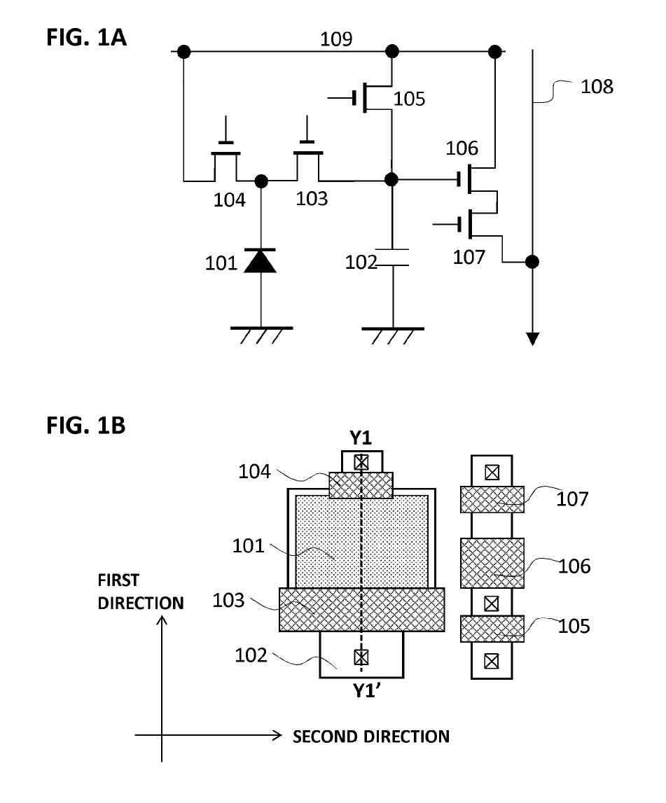

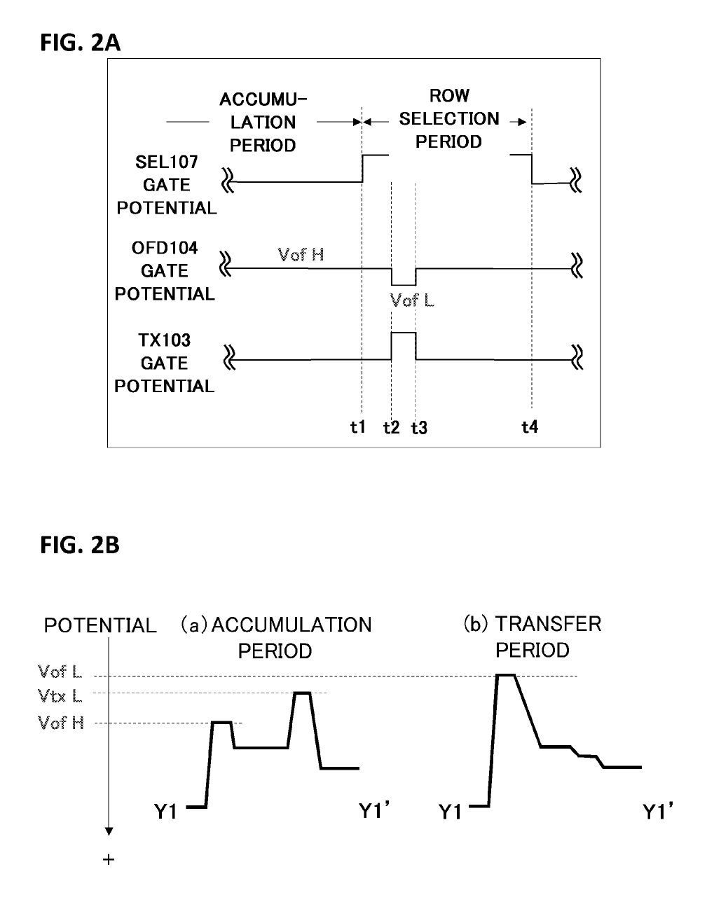

FIGS. 1A and 2B are each a schematic view illustrating the outline of a photoelectric conversion device according to First Embodiment. FIG. 1A is a circuit diagram thereof; FIG. 1B is a plan view of FIG. 1A; FIG. 2A is a timing view for driving a pixel; and FIG. 2B is a potential view along Y1-Y1′ of FIG. 1B. Below, for simplification of description, a description will be given with a first conductivity type as an N type, and with a second conductivity type as a P type. However, it is also acceptable that the first conductivity type is a P type, and that the second conductivity type is an N type.

As shown in FIG. 1A, a photoelectric conversion device according to the present embodiment includes a photoelectric converter 101, a floating diffusion part 102, a transfer transistor 103, and an overflow transistor (OFD transistor) 104. The photoelectric conversion device according to the present embodiment further includes a reset transistor 105, a source follower 106, a selection transistor 107, a vertical output line 108, and a power supply 109.

The photoelectric converter 101 generates and accumulates charges according to an incident light. The floating diffusion (hereinafter, FD) part 102 receives the charges from the photoelectric converter 101, and converts the charges into a voltage. The transfer transistor (hereinafter, TX 103) transfers the charges generated by and accumulated at the photoelectric converter 101 to the FD 102 when turned into the on state. The OFD transistor 104 discharges the charges from the photoelectric converter 101 to an overflow drain when turned into the on state. Control of the OFD transistor 104 to off starts accumulation of charges by the photoelectric converter 101. This can freely set the exposure time length. The reset transistor 105 discharges the charges transferred to the FD 102 when turned into the on state. The source follower (hereinafter, SF) 106 amplifies and outputs the voltage converted at the FD 102. The floating diffusion part 102 and the SF 106 correspond to the amplifier in the present invention. The selection transistor 107 controls the output from the SF 106, and is connected with the vertical output line 108.

As shown in FIG. 1B, the photoelectric converter 101 has a rectangular shape with a first direction and a second direction as sides. The gate electrode of the OFD transistor 104 is provided at the side along the first direction. Namely, the OFD transistor 104 is provided along the end of the photoelectric converter 101.

In FIG. 2A, the period of before time t1 is an accumulation period in which the photoelectric converter 101 accumulates charges, where the OFD transistor 104 is set at a prescribed potential VofH. During the accumulation period, as shown in FIG. 2B(a), charges are accumulated in the region surrounded by the mountains of the potential VofH formed immediately under the OFD transistor 104 and a potential VtxL formed immediately under the TX 103. As a result, when a high-brightness subject is imaged, the excess charges overflowed from the photoelectric converter 101 are discharged to the OFD transistor 104, which enables prevention of color mixture to the adjacent pixel. Incidentally, in FIG. 2B(a), VtxL assumes a potential between VofL and VofH, but is not limited thereto. VtxL may be lower than VofL, or higher than VofH.

The period of from times t1 to t4 is a row selection period in which the SEL 107 is turned on. The period of times t2 to t3 is a transfer period in which the TX 103 is turned on, wherein charges are transferred from the photoelectric converter 101 to the FD 104. At this step, the OFD transistor 104 is set at a prescribed potential VofL in at least some period during the transfer period. In FIG. 2A, over the entire period during the transfer period, the OFD transistor 104 is set at the potential of VofL. The potential at this step is shown in FIG. 2B(b). In this manner, a larger reverse bias is applied between the photoelectric converter 101 and the OFD transistor 104. This enables promotion of depletion of the photoelectric converter 101, so that the transfer efficiency can be improved. Herein, the VofL is a lower potential than the VofH.

In FIG. 2A, during the entire transfer period (times t2 to t3), the OFD transistor 104 is set at a prescribed potential VofL, and may only be set at a prescribed potential VofL in at least some period during the transfer period. This can improve the transfer efficiency as compared with the case where the potential of the OFD transistor 104 is not switched to VofL during the transfer period.

### Second Embodiment

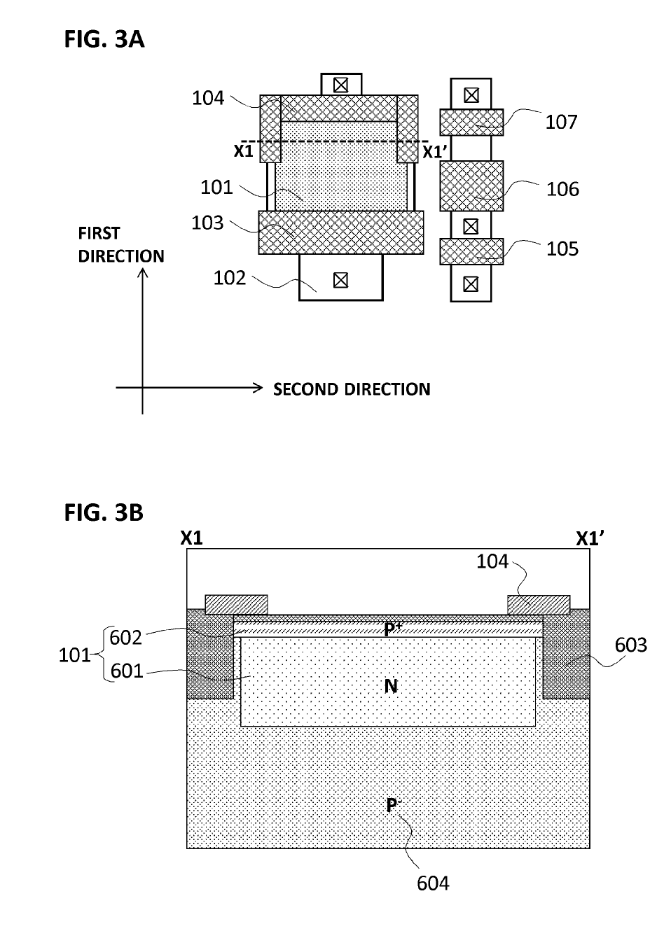

Second Embodiment of the present invention is different from First Embodiment in the shape of the gate electrode of the OFD transistor 104. Below, the difference from First Embodiment will be mainly described. FIGS. 3A and 3B are respectively a plan schematic view and a cross sectional schematic view of a photoelectric conversion device according to the present embodiment.

As shown in FIG. 3A, the gate electrode of the OFD transistor 104 is provided in a shape extending so as to surround the photoelectric converter 101. Specifically, the gate electrode of the OFD transistor 104 is provided across the entire side (first side) along the first direction of the photoelectric converter 101, and a part of the side (second side) along the second direction connected with the side. With such a configuration, when the TX 103 is turned on, and the gate electrode of the OFD transistor 104 is applied with VofL, a large reverse bias is applied to the periphery of the photoelectric converter 101. This enables a further improvement of the transfer efficiency.

Further, the VofH to be applied to the gate electrode of the OFD transistor 104 during the accumulation period is desirably a lower potential than the well potential. This enables control of the dark current.

In FIG. 3B, the photoelectric converter 101 includes a first conductivity type diffusion layer 601, and a second conductivity type diffusion layer 602. A pixel isolation part 603 is formed by, for example, shallow trench isolation (STI) separation, local oxidation of silicon (LOCOS) separation, or second conductivity type diffusion layer separation. A reference numeral 604 is a second conductivity type well region.

### Third Embodiment

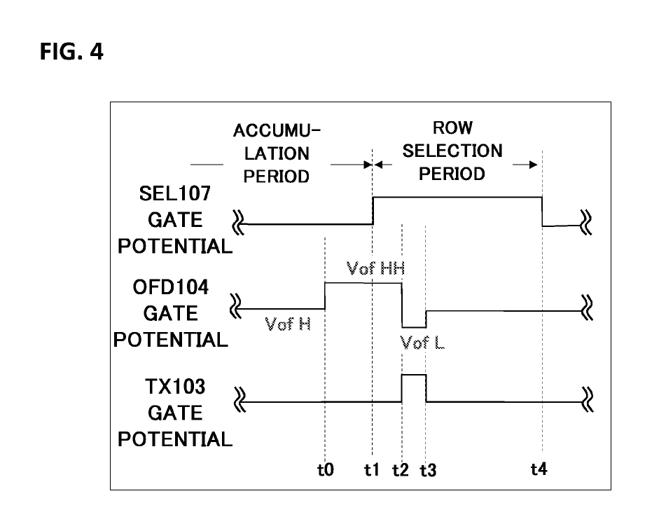

Third Embodiment of the present invention is different from First Embodiment in the gate potential set for the OFD transistor 104. Below, the difference from First and Second Embodiments will be mainly described. FIG. 4 is a timing view for driving the pixels in the present embodiment.

In FIG. 4, before time t0, the gate potential of the OFD transistor 104 is a prescribed potential VofH, and changes from VofH to a prescribed potential VofHH at time t0. VofHH is a higher potential than VofH. By performing such control, when a particularly high-brightness subject is imaged, the saturation of the amount of charges accumulated at the photoelectric converter 101 can be suppressed, thereby to obtain an image with less whiteout.

Herein, the gate potential of the OFD transistor 104 is switched from VofH to OofHH at time t0. However, the gate potential during the accumulation period may be selected from any one potential of VofH or VofHH according to the brightness of the subject.

In at least some period during the transfer period (times t2 to t3) in which the TX 103 is turned on, the gate potential of the OFD transistor 104 is set at VofL, as with First Embodiment. Incidentally, in FIG. 4, the potential is switched from the potential VofHH to VofL, but it does not matter if there is a period in which VofH is kept during the period.

### Fourth Embodiment

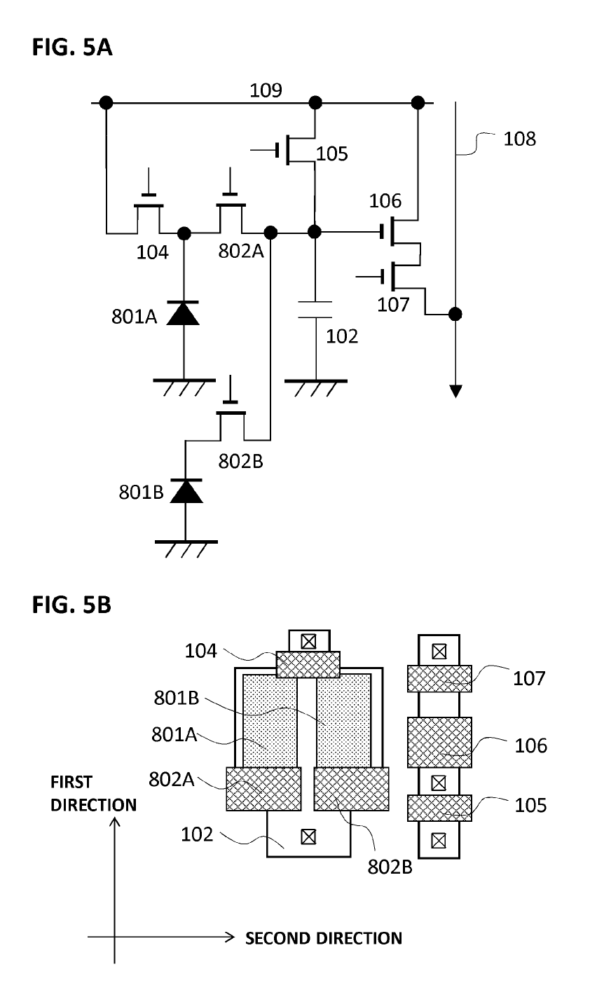

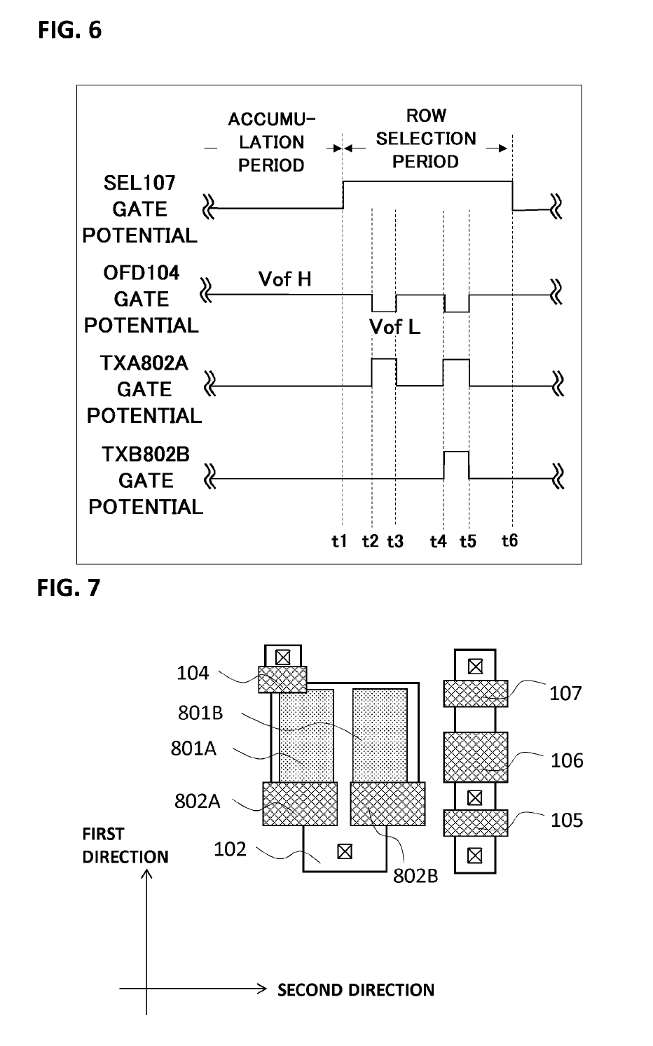

Fourth Embodiment of the present invention is a photoelectric conversion device in which one pixel has two photoelectric converters. FIGS. 5A, 5B, and 6 are respectively a circuit diagram, a plan schematic view, and a timing view of the photoelectric conversion device according to the present Fourth Embodiment.

As shown in FIG. 5A, the photoelectric conversion device according to the present embodiment has two photoelectric converters 801A and 801B in one pixel, and share one FD 102. Further, the photoelectric conversion device has a transfer transistor 802A (hereinafter, TXA) for transferring signal charges generated at the photoelectric converter 801A to the FD 102, and a transfer transistor 802B (hereinafter, TXB) for transferring signal charges generated at the photoelectric converter 802B to the FD 102. According to the configuration of the present embodiment, it is possible to accumulate signal charges to be used for uses other than imaging in addition to imaging signal charges. The signals other than those for imaging include, for example, a signal for focus detection by a phase difference detection method, a signal for distance measurement, and a signal resulting from photoelectric conversion of lights of different wavelength regions.

As shown in FIG. 5B, in the present embodiment, the gate electrode of the OFD transistor 104 is provided across both of the photoelectric converters 801A and 801B.

In FIG. 6, the period of before time t1 is an accumulation period in which the photoelectric converters 801A and 801B accumulate charges, wherein the OFD transistor 104 is set at a prescribed potential VofH. As a result, when a high-brightness subject is imaged, the excess charges overflowed from the photoelectric converters 801A and 801B are discharged to the OFD transistor 104, which enables prevention of color mixture to the adjacent pixel.

The period of from times t1 to t6 is a row selection period in which the SEL 107 is turned on. The period of from times t2 to t3 is a first transfer period in which the TXA 802A is turned on, wherein charges are transferred from the photoelectric converter 801A to the FD 102. At this step, the OFD transistor 104 is at a prescribed potential VofL in at least some period during the transfer period. As a result, a larger reverse bias is applied between the photoelectric converter 801A and the OFD transistor 104. This enables promotion of depletion of the photoelectric converter 801A, so that the transfer efficiency can be improved. Herein, VofL is a lower potential than VofH.

The period of from times t4 to t5 is a second transfer period in which both of the TXA 802A and the TXB 802B are turned on, wherein charges are transferred from the photoelectric converters 801A and 801B to the FD 102. At this step, the OFD transistor 104 is at a prescribed potential VofL in at least some period during the transfer period. As a result, a larger reverse bias is applied between both of the photoelectric converters 801A and 801B and the OFD transistor 104. This enables promotion of depletion of the photoelectric converters 801A and 801B, so that the transfer efficiency can be improved.

In the present embodiment, during all of the first transfer period (t2 to t3) and the second transfer period (t4 to t5), the OFD transistor 104 is set at a potential VofL, and may only be set at a potential VofL in at least some period during each transfer period. Further, during the period of from times t3 to t4, the potential of the OFD transistor 104 is set at VofH, but may also be set at VofL during this period.

### Fifth Embodiment

Fifth Embodiment of the present invention is different from Fourth Embodiment in the configuration of the OFD transistor 104. FIG. 7 is a plan schematic view of the outline of a photoelectric conversion device according to the present embodiment.

In FIG. 7, the OFD transistor 104 is provided only at the end of the photoelectric converter 801A. With such a configuration, when the pixel is driven at the timing of FIG. 6, during the period of from times t2 to t3, and from t4 to t5, it is possible to promote the depletion of the photoelectric converter 801A, so that the transfer efficiency can be improved. Further, as compared with Fourth Embodiment, the OFD transistor 104 can be made smaller, so that the pixel can be miniaturized.

### Sixth Embodiment

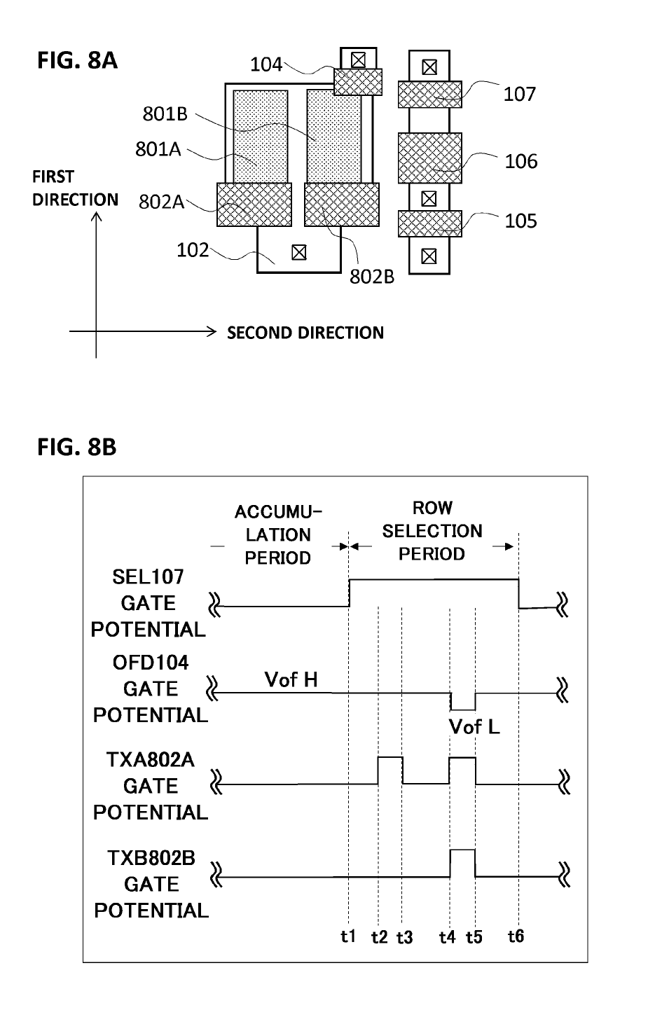

Sixth Embodiment of the present invention is different from Fourth and Fifth Embodiments in the configuration of the OFD transistor 104, and is accordingly different in the driving timing of the pixel. FIGS. 8A and 8B are respectively a plan schematic view and a timing view of a photoelectric conversion device according to the present embodiment.

In FIG. 8A, the OFD transistor 104 is provided only at the end of the photoelectric converter 801B.

The difference in pixel driving timing of the present embodiment from Fourth Embodiment (the difference between FIGS. 8B and 6) resides in that the OFD transistor 104 is at VofH at from times t2 to t3. During the period of times t4 to t5, the depletion of the photoelectric converter 801B can be promoted, thereby to improve the transfer efficiency. Further, as compared with Fourth Embodiment, the OFD transistor 104 can be reduced in size, thereby to miniaturize the pixels.

### Seventh Embodiment

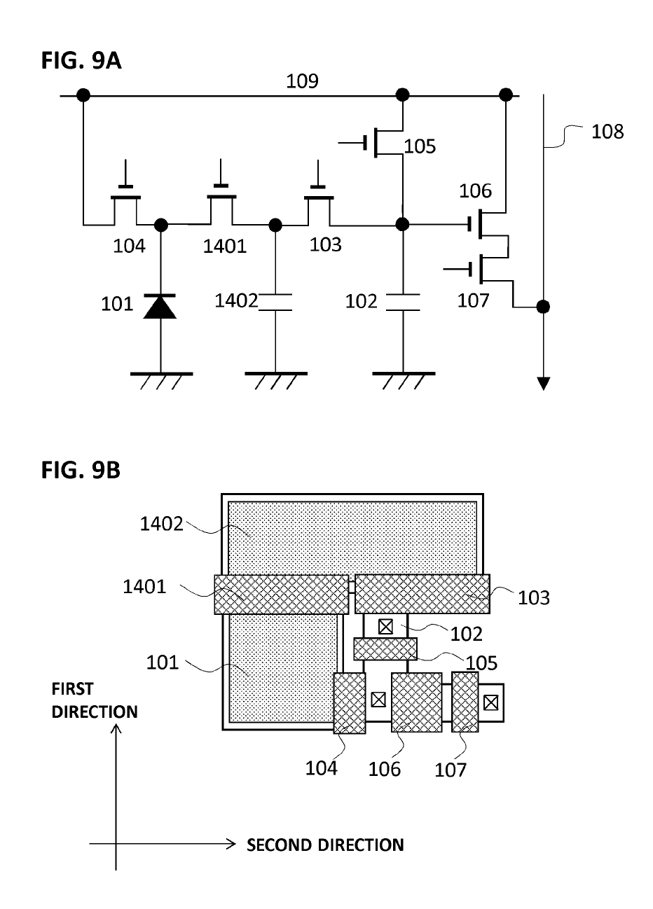

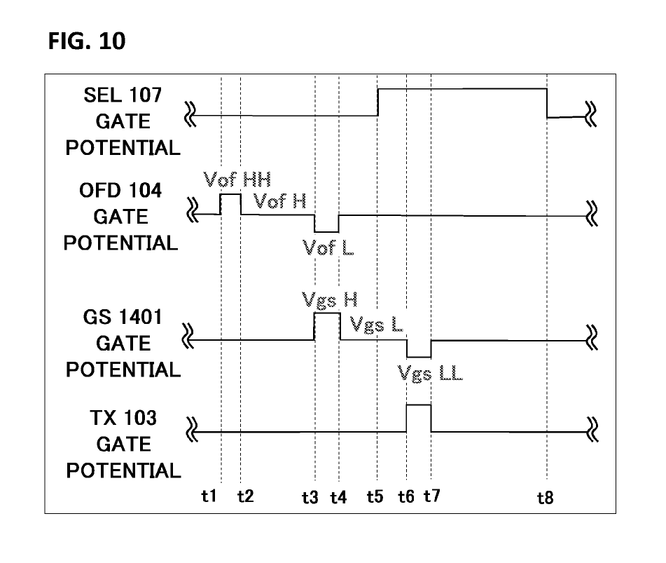

Seventh Embodiment of the present invention is a photoelectric conversion device for performing a global electronic shutter operation. FIGS. 9A, 9B, and 10 are respectively a circuit diagram, a plan view, and a timing view of the photoelectric conversion device according to the present embodiment.

As shown in FIG. 9A, the photoelectric conversion device according to the present embodiment further includes a second transfer transistor 1401 and a memory part 1402 at each pixel. The second transfer transistor (hereinafter, GS) 1401 transfers charges from the photoelectric converter 101 to the memory part 1402 during the on state. The memory part 1402 is a charge holding part for temporarily holding charges. In the present embodiment, the transfer transistor (TX) 103 transfers charges from the memory part 1402 to the FD 102 during the on state.

With such a circuit configuration, it becomes possible to transfer the charges accumulated at the photoelectric converter 101 to the memory part 1402 and to hold the charges at the same time. Namely, by having a function of global electronic shutter, it is possible to image an image with less distortion.

As shown in FIG. 9B, the OFD transistor 104 is provided along the end of the photoelectric converter 101.

In FIG. 10, the period of from times t1 to t2 is the period in which the OFD transistor 104 is turned on, thereby to reset the charges at the photoelectric converter 101. During this period, the gate electrode of the OFD transistor 104 is applied with a prescribed potential VofHH.

The period of from times t2 to t3 is the accumulation period in which charges are accumulated at the photoelectric converter 101. In this period, the gate electrode of the OFD transistor 104 is set at a prescribed potential VofH. Herein, VofH is a lower potential than VofHH, and is a proper potential for suppressing color mixture to the adjacent pixel.

The period of from times t3 to t4 is a first transfer period in which the GS 1401 is turned one, thereby to transfer charges from the photoelectric converter 101 to the memory part 1402. At this step, the gate electrode of the GS 1401 is set at a prescribed potential VgsH. Further, the gate potential of the OFD transistor 104 is set at a prescribed potential VofL in at least some period during the first transfer period. As a result, a larger reverse bias is applied between the photoelectric converter 101 and the OFD transistor 104. This enables promotion of depletion of the photoelectric converter 101, so that the transfer efficiency can be improved. Herein, VgsH is a higher potential than VgsL, and VofL is a lower potential than VofH.

The period of from times t5 to t8 is the row selection period in which the SEL 107 is turned on. The period of from times t6 to t7 is a second transfer period in which the TX 103 is turned on, wherein the charges held at the memory part 1402 are transferred to the FD 102. At this step, the GS 1401 is changed from a prescribed potential VgsL to a prescribed potential VgsLL in at least some period during the second transfer period. As a result, a larger reverse bias is applied between the memory part 1402 and the GS 1401, which enables promotion of depletion of the memory part 1402. Thus, the transfer efficiency can be improved. Herein, VgsL is a higher potential than VgsLL, and a potential for relaxing the reverse bias between the GS 1401 and the photoelectric converter 101, and between the GS 1401 and the memory part 1402, and not largely damaging the charge capacity of the photoelectric converter 101 and the memory part 1402 during the accumulation period.

### Eighth Embodiment

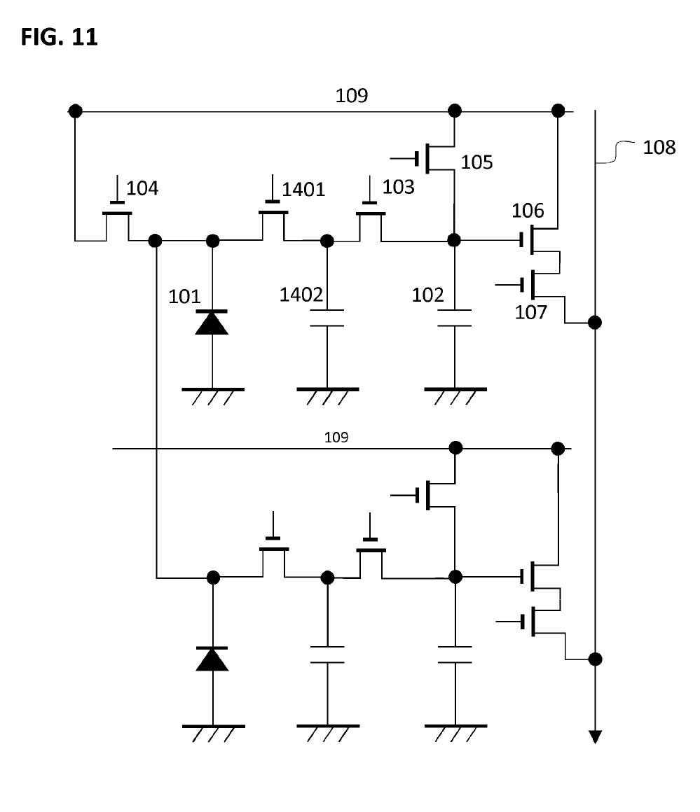

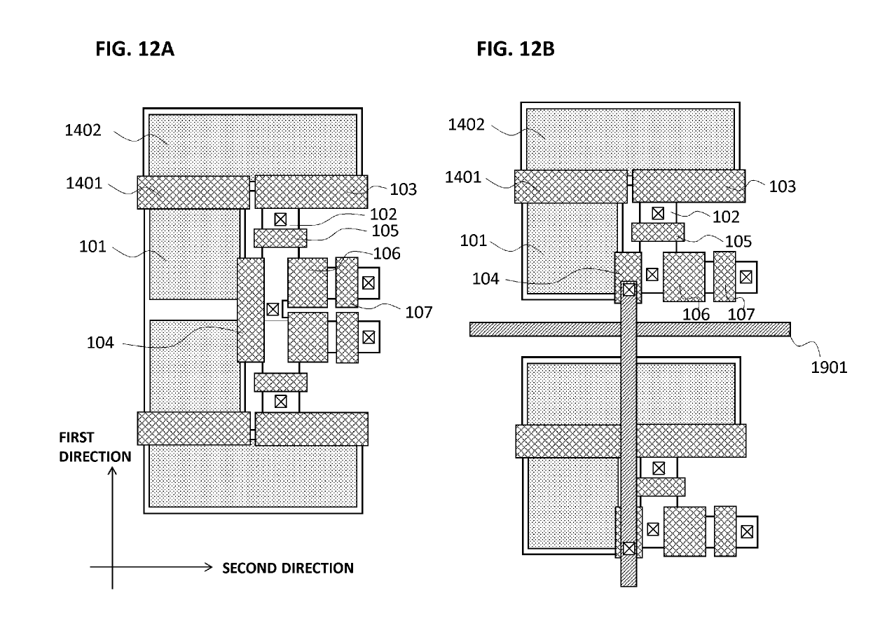

Eighth Embodiment of the present invention is different from Seventh Embodiment in that one OFD 104 is provided for every two pixels. FIG. 11 is a circuit diagram of a photoelectric conversion device according to the present embodiment. FIGS. 12A and 12B are each a plan view of a configuration capable of implementing the present embodiment. FIGS. 11 to 12B all each show a configuration for two pixels.

As shown in FIG. 11, the OFD transistor 104 is shared among a plurality of pixels.

FIG. 12A shows a realized example of the present embodiment. In FIG. 12A, the pixels adjacent in the first direction are mirror symmetrically provided. The gate electrode of the OFD transistor 104 is provided across the sides along the second direction of the photoelectric converter 101 of two pixels, and shared between the two pixels. The OFD transistor 104 is shared, and hence, exactly the same potential is supplied to the OFD transistor 104 of each pixel. Thus, the potential distribution during the first transfer period is formed mirror symmetrically with respect to the OFD transistor 104 as the center. Therefore, the transfer efficiency variation of the GS 1401 in each pixel is suppressed, so that an image with less roughness can be acquired.

FIG. 12B shows another realized example of the present embodiment. In FIG. 12B, pixels adjacent in the first direction are arranged translationally symmetrically. In this example, the driving wire 1901 of the OFD transistor 104 is shared. Therefore, as with FIG. 12A, the transfer efficiency variation of the GS 1401 in each pixel is suppressed, so that an image with less roughness can be acquired.

### Ninth Embodiment

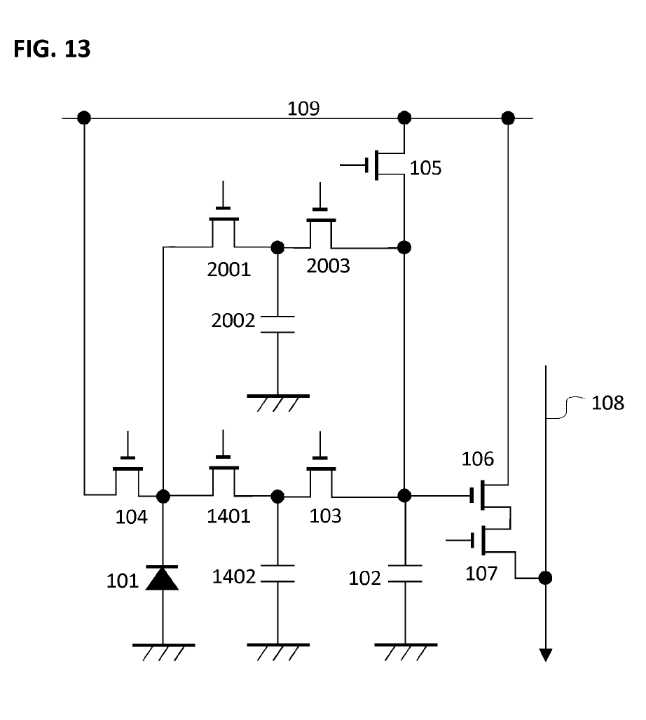

Ninth Embodiment of the present invention is a photoelectric conversion device including two memory parts for a global electronic shutter. FIGS. 13 to 15 are respectively a circuit diagram, a plan view, and a timing view of the photoelectric conversion device according to the present embodiment.

As shown in FIG. 13, a pixel in an imaging device according to the present embodiment has a third transfer transistor 2001, a second memory part 2002, and a fourth transfer transistor 2003 in addition to the configuration of Seventh Embodiment (FIG. 9A). Herein, the second transfer transistor 1401 is referred to as transistor GSA 1401, and the third transfer transistor 2001 is referred to as transistor GSB 2001. Further, the transfer transistor 103 is referred to as transistor TXA 103, and the fourth transfer transistor 2003 is referred to as transistor TXB 2003. The transistor GSB 2001 transfers charges from the photoelectric converter 101 to the second memory part 2002 during the on state. The transistor TXB 2003 transfers charges from the second memory part 2002 to the FD 102 during the on state.

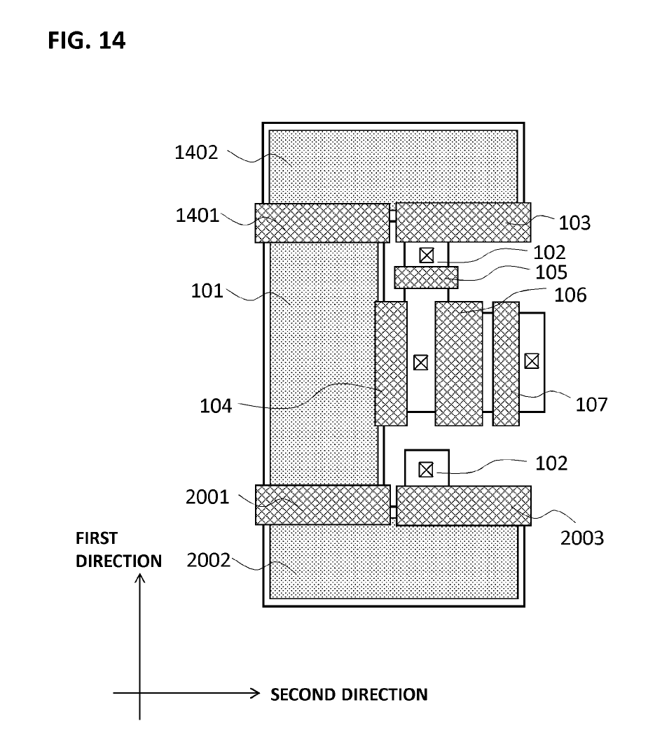

As shown in FIG. 14, the photoelectric converter 101 assumes a configuration surrounded by the transistor GSA 1401, the transistor GSB 2001, and the OFD transistor 104.

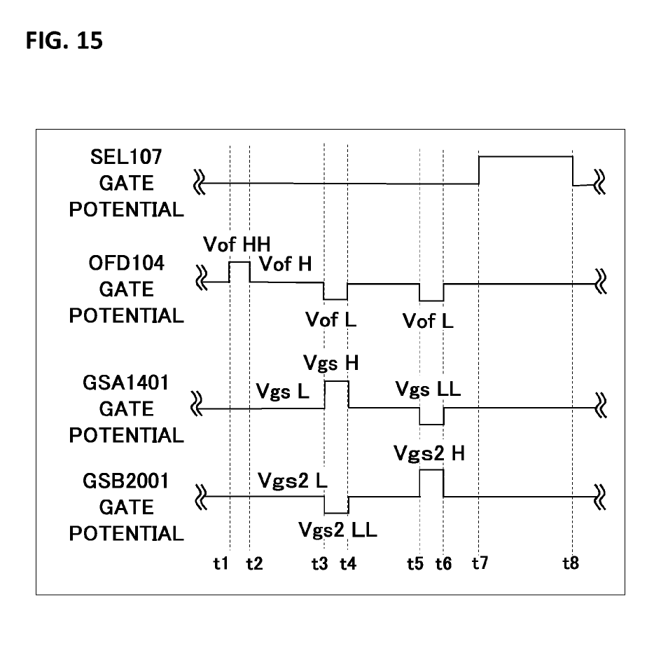

In FIG. 15, the period of from times t1 to t2 is a period in which the OFD transistor 104 is turned on, thereby to reset the charges of the photoelectric converter 101. During this period, the gate electrode of the OFD transistor 104 is applied with a prescribed potential VofHH.

The period of from times t2 to t3 is the accumulation period in which charges are accumulated at the photoelectric converter 101. During this period, the gate electrode of the OFD transistor 104 is applied with a prescribed potential VofH, and the GS 2001 is applied with a prescribed potential Vgs2L. Herein, VofH is a lower potential than VofHH, and a proper potential for suppressing color mixture to the adjacent pixel.

The period of from times t3 to t4 is a first transfer period in which the GS 1401 is turned on, so that charges are transferred from the photoelectric converter 101 to the memory part 1402. At this step, the OFD transistor 104 and the GS 2001 are applied with prescribed potentials VofL and Vgs2LL in at least some period during the first transfer period, respectively. As a result, a larger reverse bias is applied between the photoelectric converter 101 and the OFD transistor 104, and between the photoelectric converter 101 and the GS 2001. This enables promotion of depletion of the photoelectric converter 101, so that the transfer efficiency can be further improved. Herein, Vgs2LL is a lower potential than Vgs2L. Further, Vgs2L is a proper potential not largely damaging the charge capacity of the photoelectric converter 101 and the memory part 2002.

The period of from times t5 to t6 is a second transfer period in which the GS 2001 is turned on, so that charges are transferred from the photoelectric converter 101 to the memory part 2002. At this step, the OFD transistor 104 and the GS 1401 are applied with prescribed potentials VofL and VgsLL in at least some period during the second transfer period, respectively. As with the first transfer period, it becomes possible to improve the transfer efficiency.

### Tenth Embodiment

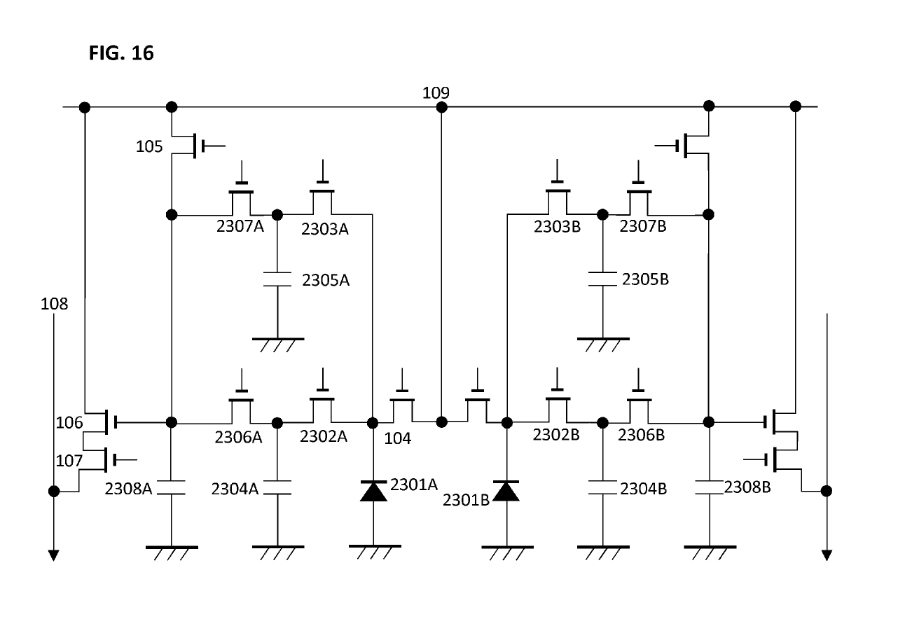

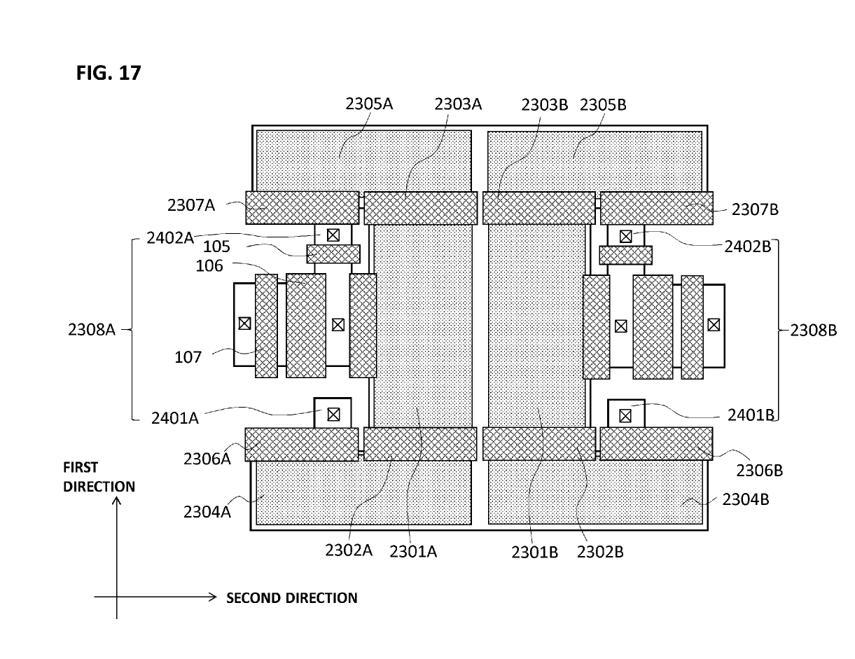

Tenth Embodiment of the present invention is a photoelectric conversion device including the configuration of Ninth Embodiment double in one pixel. FIGS. 16 and 17 are respectively a circuit diagram and a plan schematic view of the photoelectric conversion device according to the present embodiment.

As shown in FIG. 16, in the present embodiment, the photoelectric conversion device has two photoelectric converters 2301A and 2301B, and two FD 2308A and 2308B in one pixel. Further, the photoelectric conversion device has transfer transistors 2302A and 2303A for transferring the signal charges generated at the photoelectric converter 2301A to the memory parts 2304A and 2305A. Similarly, the photoelectric conversion device has transfer transistors 2302B and 2303B for transferring signal charges generated at the photoelectric converter 2301B to the memory parts 2304B and 2305B. Further, the photoelectric conversion device has transfer transistors 2306A and 2307A for transferring charges from the memory parts 2304A and 2305A to the FD 2308A. Similarly, the photoelectric conversion device has transfer transistors 2306B and 2307B for transferring charges from the memory parts 2304B and 2305B to the FD 2308B.

In FIG. 17, the FD 2308A includes first conductivity type diffusion layers 2401A and 2402A. Similarly, the FD 2308B includes first conductivity type diffusion layers 2401B and 2402B. Herein, the first FD 2308A and the second FD 2308B are respectively assumed to be independent nodes, but may be shared. Further, the diffusion layers 2401A and 2402A, and the diffusion layers 2401B and 2402B were assumed to be shared, respectively. However, of the diffusion layers 2401A, 2402A, 2401B, and 2402B, the combinations for sharing are not limited to the present embodiment. For example, the diffusion layers 2401A and 2401B, and the diffusion layers 2402A and 2402B may be shared, respectively.

The driving timing of pixels in the present embodiment is the same as in Ninth Embodiment (FIG. 15), and hence will not be described.

According to the configuration of the present embodiment, it is possible to accumulate signal charges for use in other uses than imaging in addition to signal charges for imaging. Examples of the signals for other use than imaging include signals for focus detection by a phase difference detection method, signals for distance measurement, and signals obtained by photoelectrically converting lights of different wavelength regions.

### Eleventh Embodiment

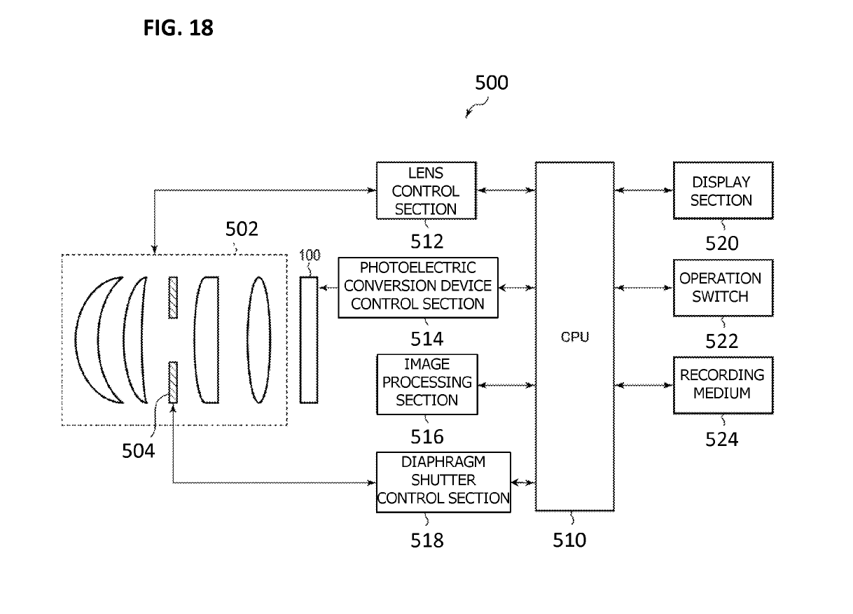

A photoelectric conversion system according to Eleventh Embodiment of the present invention will be described by reference to FIG. 18. FIG. 18 is a block view showing a schematic configuration of the photoelectric conversion system according to the present embodiment.

The photoelectric conversion devices described in the First to Tenth Embodiments are applicable to various photoelectric conversion systems. The applicable photoelectric conversion systems have no particular restriction. Examples thereof may include various devices such as digital still camera, digital camcorder, surveillance camera, copier, fax, cellular phone, vehicle-mounted camera, observation satellite, and medical camera. Further, a camera module including an optical system such as lens, and a photoelectric conversion device is also included in the photoelectric conversion systems. FIG. 18 shows a block view of a digital still camera as one example thereof.

A photoelectric conversion system 500 includes, as shown in FIG. 18, a photoelectric conversion device 100, an imaging optical system 502, a CPU 510, a lens control part 512, a photoelectric conversion device control part 514, an image processing part 516, a diaphragm shutter control part 518, a display part 520, an operation switch 522, and a recording medium 524.

The imaging optical system 502 is an optical system for forming an optical image of a subject, and includes a lens group, a diaphragm 504, and the like. The diaphragm 504 has a function of adjusting the aperture diameter, and thereby performing the light amount adjustment for photographing, and additionally also has a function as an exposure second time adjusting shutter at the time of photographing a still image. The lens group and the diaphragm 504 are held forwardly and backwardly movably along the optical axis direction. The interlocking operations thereof implements the scaling function (zooming function) and the focus adjusting function. The imaging optical system 502 may be integrated with the photoelectric conversion system, or may be an imaging lens mountable to the photoelectric conversion system.

The photoelectric conversion device 100 is arranged so that the imaging surface is situated in the image space of the imaging optical system 502. The photoelectric conversion device 100 is each photoelectric conversion device described in First to Tenth Embodiments, and includes a CMOS sensor (pixel part) and peripheral circuits (peripheral circuit regions) thereof. With the photoelectric conversion device 100, pixels each having a plurality of photoelectric converters are two-dimensionally arranged, and a color filter is arranged with respect to the pixels, thereby to form a two-dimensional single-plate color sensor. The photoelectric conversion device 100 photoelectrically converts the subject image formed by the imaging optical system 502, and outputs the subject image as an image signal or a focus detection signal.

The lens control part 512 is for controlling the forward and backward driving of the lens group of the imaging optical system 502, and performing the scaling operation and the focus adjustment, and includes circuits and processing devices formed so as to implement the functions. The diaphragm shutter control part 518 is for changing the aperture diameter of the diaphragm 504 (with the diaphragm value variable), and adjusting the photographing light amount, and includes circuits and processing devices formed so as to implement the function.

The CPU 510 is a control device in a camera for conducting various controls of the camera main body, and includes an operation part, a ROM, a RAM, an A/D converter, a D/A converter, a communication interface circuit, and the like. The CPU 510 controls the operation of each part in the camera according to the computer program stored in the ROM, or the like, and executes a series of photographing operations such as AF including detection of the focus state (focus detection) of the imaging optical system 502, imaging, image processing, and recording. The CPU 510 is also a signal processor.

The photoelectric conversion device control part 514 is for controlling the operation of the photoelectric conversion device 100, and A/D converting the signal outputted from the photoelectric conversion device 100, and sending the signal to the CPU 510, and includes circuits and processing devices formed so as to implement the functions. The A/D conversion function may be included in the photoelectric conversion device 100. The image processing part 516 is a processing device for performing image processing such as y conversion or color interpolation on the signal subjected to A/D conversion, and generating an image signal, and includes circuits and processing devices formed so as to implement the function. The display part 520 is a display device such as a liquid crystal display device (LCD), and displays information regarding the photographing mode of the camera, a preview image before photographing, a confirmation image after photographing, the focusing state at the time of focus detection, and the like. The operation switch 522 includes a power supply switch, a release (photographing trigger) switch, a zoom operation switch, a photographing mode selection switch, and the like. The recording medium 524 is for recording an photographed image, and the like, and may be internally included in the photoelectric conversion system, or may be a detachable one such as a memory card.

In this manner, the photoelectric conversion system 500 to which each photoelectric conversion device 100 according to First to Tenth Embodiments is applied is formed. As a result, it is possible to implement a high-performance photoelectric conversion system.

### Twelfth Embodiment

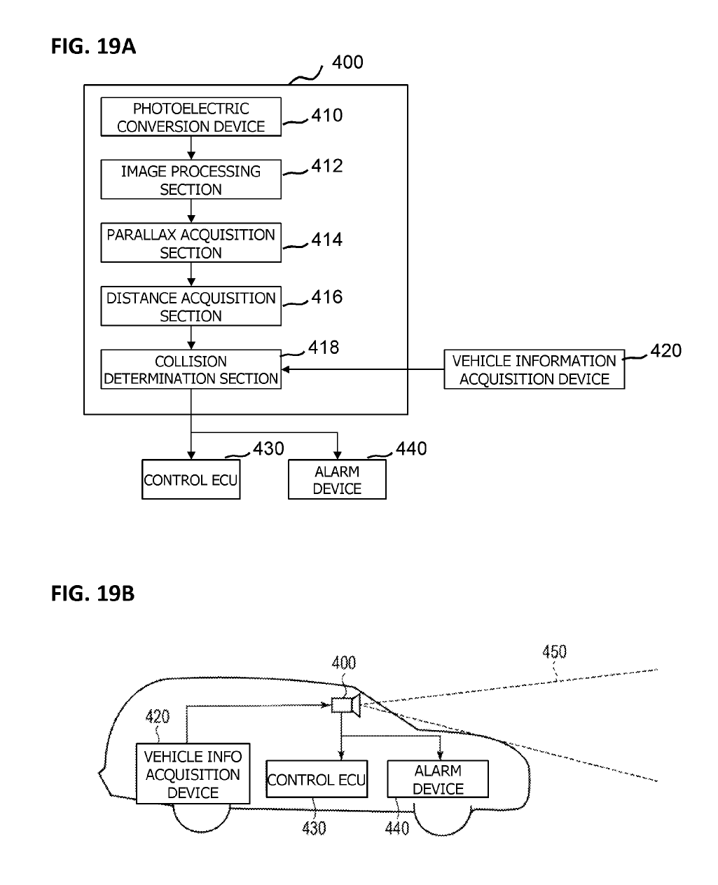

A photoelectric conversion system and a moving body according to Twelfth Embodiment of the present invention will be described by reference to FIGS. 19A and 19B. FIGS. 19A and 19B are each a view showing the configuration of the photoelectric conversion system and the moving body according to the present embodiment.

FIG. 19A shows one example of an photoelectric conversion system 400 regarding a vehicle-mounted camera. The photoelectric conversion system 400 has a photoelectric conversion device 410. The photoelectric conversion device 410 is any of the photoelectric conversion devices described in the First to Tenth Embodiments. The photoelectric conversion system 400 has an image processing part 412 of a processing device for performing image processing on a plurality of image data acquired by the photoelectric conversion device 410, and a parallax acquisition part 414 of a processing device for performing calculation of parallax (phase difference between parallax images) from a plurality of image data acquired from the photoelectric conversion device 410. Further, the photoelectric conversion system 400 has a distance acquisition part 416 of a processing device for calculating the distance to the object based on the calculated parallax, and an impact determination part 418 of a processing device for determining whether there is an impact possibility or not based on the calculated distance. Herein, the parallax acquisition part 414 or the distance acquisition part 416 is one example of information acquisition means for acquiring information such as the distance to the object. Namely, the distance information is information regarding the parallax, the defocus amount, the distance to the object, and the like. The impact determination part 418 may determine the impact possibility using any of the distance information. The processing device may be implemented by hardware designed for exclusive use, or may be implemented by general-purpose hardware for performing operations based on a software module. Further, the processing device may be implemented by a field programmable gate array (FPGA), an application specific integrated circuit (ASIC), or the like, or may be implemented by a combination thereof.

The photoelectric conversion system 400 is connected with a vehicle information acquisition device 420, and can acquire vehicle information such as the vehicle speed, the yaw rate, and the steering angle. Further, the photoelectric conversion system 400 is connected with a control ECU 430 of a control device for outputting a control signal for generating a damping force to a vehicle based on the determination result at the impact determination part 418. Namely, the control ECU 430 is one example of moving body control means for controlling the moving body based on the distance information. Further, the photoelectric conversion system 400 is also connected with an alarm device 440 for issuing an alarm to a driver based on the determination result at the impact determination part 418. For example, when the impact possibility is high as the determination result of the impact determination part 418, the control ECU 430 brakes, returns the accelerator, suppresses the engine output, or performs other operations, and thereby performs vehicle control of avoiding an impact, and reducing the damage. The alarm device 440 sounds an alarm such as a sound, displays alarm information on a screen of a car navigation system, or the like, applies a vibration to a sheet belt or a steering, or performs other operations, and thereby warns a user.

In the present embodiment, the periphery such as the front or the back of a vehicle is imaged by the photoelectric conversion system 400. FIG. 19B shows the photoelectric conversion system 400 when the vehicle front (imaging region 450) is imaged. The vehicle information acquisition device 420 sends an instruction for the photoelectric conversion system 400 to operate, and to execute imaging. By using each photoelectric conversion device of the First to Tenth Embodiments as the photoelectric conversion device 410, the photoelectric conversion system 400 of the present embodiment can be more improved in distance measurement precision.

In the description up to this point, a description has been given to the example in which control is performed so as to prevent the impact with another vehicle. However, the present invention is also applicable to control of following another vehicle for automatic driving, control of automatically driving so as not to deviate from the lane, and the like. Further, the photoelectric conversion system is applicable to moving bodies (transport devices) such as ships, aircrafts, or industrial robots, not limited to vehicles such as cars. The moving bodies (transport devices) are various driving sources such as an engine, a motor, a wheel, and a propeller. In addition, the present invention is applicable to devices widely using object recognition such as Intelligent transport system (ITS), not limited to the moving bodies.

### Other Embodiments

The photoelectric conversion device may have a structure (chip lamination structure) of lamination of a first semiconductor chip including pixels provided therein, and a second semiconductor chip including a read circuit (amplifier) provided therein. The read circuits (amplifiers) in the second semiconductor chip can be each a row circuit corresponding to the pixel row of the first semiconductor chip. Further, the read circuits (amplifiers) in the second semiconductor chip can each be a matrix circuit corresponding to the pixel or the pixel block of the first semiconductor chip. For the connection between the first semiconductor chip and the second semiconductor chip, there can be adopted connection by through electrode (TSV), interchip wiring by direct junction of a metal such as copper (Cu), interchip microbumping, or the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2018-25382, filed on Feb. 15, 2018, which is hereby incorporated by reference herein in its entirety.

What is claimed is:

1. A photoelectric conversion device, comprising a plurality of pixels each including:
a photoelectric converter for accumulating charges generated by photoelectric conversion;
a transfer transistor for transferring the charges accumulated at the photoelectric converter; and
an overflow transistor for connecting the photoelectric converter with an overflow drain,
wherein during an accumulation period in which the charges are accumulated at the photoelectric converter, a gate potential of the overflow transistor is set at a potential VofH, and
wherein in at least some period during a transfer period in which the charges are transferred from the photoelectric converter by the transfer transistor, the gate potential of the overflow transistor is set at a potential VofL that is lower than the potential VofH.

2. The photoelectric conversion device according to claim 1,
wherein each of the plurality of pixels further includes an amplifier for outputting a signal based on charges, and
wherein the transfer transistor is a transistor for transferring the charges accumulated at the photoelectric converter to the amplifier.

3. The photoelectric conversion device according to claim 2, wherein at least a part of a gate electrode of the overflow transistor is arranged across a first side of the photoelectric converter, and at least a part of a second side of the photoelectric converter, the second side being connected with the first side.

4. The photoelectric conversion device according to claim 2, wherein, during the accumulation period, the gate potential of the overflow transistor is set at the potential VofH and a potential VofHH that is higher than the potential VofH.

5. The photoelectric conversion device according to claim 2,
wherein the photoelectric converter includes a first photoelectric converter and a second photoelectric converter,
wherein the transfer transistor includes a transistor TXA for transferring charges accumulated at the first photoelectric converter to the amplifier, and a transistor TXB for transferring charges accumulated at the second photoelectric converter to the amplifier,
wherein a gate electrode of the overflow transistor is connected with any one or both of the first photoelectric converter and the second photoelectric converter, and
wherein in at least some period during a transfer period in which the charges of the photoelectric converter connected with the gate electrode of the overflow transistor are transferred to the amplifier, the gate potential of the overflow transistor is set at the potential VofL.

6. The photoelectric conversion device according to claim 1,
wherein each of the plurality of pixels includes:
the photoelectric converter for accumulating charges generated by photoelectric conversion;
a charge holding part for holding charges;
an amplifier for outputting a signal based on charges;
a first transfer transistor for transferring the charges accumulated at the photoelectric converter to the charge holding part; and
wherein a second transfer transistor for transferring the charges held at the charge holding part to the amplifier, and
wherein the transfer transistor for transferring the charges accumulated at the photoelectric converter is the first transfer transistor.

7. The photoelectric conversion device according to claim 6, wherein, during the accumulation period, the gate potential of the overflow transistor is set at the potential VofH and a potential VofHH that is higher than the potential VofH.

8. The photoelectric conversion device according to claim 6, p1 wherein a gate potential of the first transfer transistor assumes at least three potentials of VgsH, VgsL, and VgsLL (VgsH>VgsL>VgsLL),
wherein during the accumulation period, the gate potential of the first transfer transistor is set at the potential VgsL,
wherein during a transfer period in which charges are transferred from the photoelectric converter to the charge holding part, the gate potential of the first transfer transistor is set at the potential VgsH, and
wherein in at least some period during a transfer period in which charges are transferred from the charge holding part to the amplifier, the gate potential of the first transfer transistor is set at the potential VgsLL.

9. The photoelectric conversion device according to claim 6, wherein two of the pixels share one of the overflow transistors.

10. The photoelectric conversion device according to claim 6,
wherein the charge holding part includes a first charge holding part and a second charge holding part,
wherein the first transfer transistor includes a transistor GSA for transferring the charges accumulated at the photoelectric converter to the first charge holding part, and a transistor GSB for transferring the charges accumulated at the photoelectric converter to the second charge holding part, and
wherein in at least some period during a transfer period in which charges are transferred from the photoelectric converter to the first charge holding part by the transistor GSA, and in at least some period during a transfer period in which charges are transferred from the photoelectric converter to the second charge holding part by the transistor GSB, the gate potential of the overflow transistor is set at the potential VofL.

11. The photoelectric conversion device according to claim 10,
wherein in at least some period during the transfer period in which charges are transferred from the photoelectric converter to the first charge holding part by the transistor GSA, a potential of the transistor GSB is set at a higher potential than the potential during the accumulation period, and
wherein in at least some period during the transfer period in which charges are transferred from the photoelectric converter to the second charge holding part by the transistor GSB, a potential of the transistor GSA is set at a higher potential than the potential during the accumulation period.

12. An photoelectric conversion system, comprising:
the photoelectric conversion device according to claim 1; and
a signal processor for processing a signal outputted from the photoelectric conversion device.

13. A moving body, comprising:
the photoelectric conversion device according to claim 1;
a moving device;
a processing device for acquiring information from a signal outputted from the photoelectric conversion device; and
a processing device for controlling the moving device based on the information.
